(19) United States
(12) Patent Application Publication
(10) Pub. No.: US 2026/0357134 A1
(43) Pub. Date: Nov. 12, 2026

(54) PLANARIZATION SOLUTION FOR LINER PLANARIZATION

(71) Applicant: ChEmpower Corporation, Hillsboro, OR (US)

(72) Inventors: Matthias Stender, Phoenix, AZ (US); Suryadevara Babu, Portland, OR (US); Nikunjkumar Visaveliya, Potsdam, NY (US); ChangXue Wang, Minneapolis, MN (US); Sudhanshu Misra, Camas, WA (US)

(21) Appl. No.: 19/672,389

(22) Filed: May 8, 2026

Related U.S. Application Data
(60) Provisional application No. 63/803,860, filed on May 11, 2025.

(51) Int. Cl. C09K 13/00; H10P 95/00

(52) U.S. Cl. CPC C09K 13/00; H10P 95/04; H10P 95/062

(57) ABSTRACT

Examples are disclosed that relate to a planarization solution for abrasive-free planarization, the planarization solution comprising a barrier layer-activating additive. Examples are also disclosed that relate to tools and methods for performing abrasive-free planarization using a planarization solution comprising a barrier layer-activating additive.

### CROSS REFERENCE TO RELATED APPLICATIONS

This application claims priority to US Provisional Application 63/803,860, entitled “PLANARIZATION SOLUTION FOR LINER PLANARIZATION” and filed May 11, 2025, the entirety of which is hereby incorporated herein by reference for all purposes.

### BACKGROUND

Chemical mechanical planarization (CMP) is commonly used in integrated circuit fabrication processes to smooth surfaces, such as that of a semiconductor substrate, by removal of material using a combination of chemical and mechanical forces. A typical CMP process involves using an abrasive and a chemical slurry that can be corrosive to the material being removed, in combination with a polishing pad. The substrate and polishing pad are pressed together, and rotated relative to one another with non-concentric axes of rotation. The combination of the force and slurry removes areas of the substrate with a higher topology compared to areas with a lower topology, thereby smoothing the surface.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to solutions for performing abrasive-free chemical planarization of a barrier layer for a conductive copper line. The disclosed examples provide a planarization solution comprising a barrier layer-activating additive that weakens chemical bonding within the barrier layer, thereby allowing at least partial removal of the barrier layer by an abrasive-free, chemically-functionalized planarization pad. The abrasive-free, chemically-functionalized planarization pad also can comprise chelating functional groups to chelate components of the tantalum-containing barrier layer after removal.

### BRIEF DESCRIPTION OF THE FIGURES

FIG. 1 shows a block diagram of an example abrasive-free chemical planarization system.

FIGS. 2A-2B schematically illustrate planarization of an integrated circuit structure comprising copper and a barrier layer.

### DETAILED DESCRIPTION

CMP is often used to planarize a structure comprising copper deposited over a barrier layer in a trench and/or via. Example barrier layers include tantalum-containing barrier layers, which can comprise one or more of tantalum metal and/or tantalum nitride. The copper is configured to act as an electrically conductive line that connects to integrated circuit components. As copper has relatively high mobility in dielectric materials, such as silicon oxide, the barrier layer is used between the copper and an adjacent dielectric material to prevent copper diffusion. Fabrication of the copper line involves etching the via and/or trench, depositing the barrier layer (which can comprise more than one layer, such as in the case of a tantalum/tantalum nitride barrier layer), depositing the copper, and then performing CMP to planarize copper overburden and remove portions of the barrier layer that are outside of the trench and/or via.

However, current CMP methods for removal of portions of a barrier layer can pose various drawbacks. For example, barrier CMP slurries employ a high concentration of abrasive particles, most typically colloidal silica (e.g. >2% silica), and polish the barrier layer mainly due to the abrasion force of the particles. Due to the high particle loading, the barrier layer CMP process is prone to causing scratch defects on the copper lines.

Thus, examples are disclosed that relate to abrasive-free planarization solutions with one or more barrier layer-activating additives that can chemically activate a barrier layer, such as a tantalum-containing barrier layer. The additives can chemically attack the barrier layer or weaken the chemical bonds of the barrier layer so that the barrier layer can easily be removed by an abrasive-free, chemically functionalized CMP pad, which provides additional chelation to aid the removal of chemical species from the barrier layer. While disclosed herein in the context of tantalum-containing barrier layers, in other examples any other suitable barrier layer can be at least partially removed using an abrasive-free planarization solution with one or more barrier layer-activating additive.

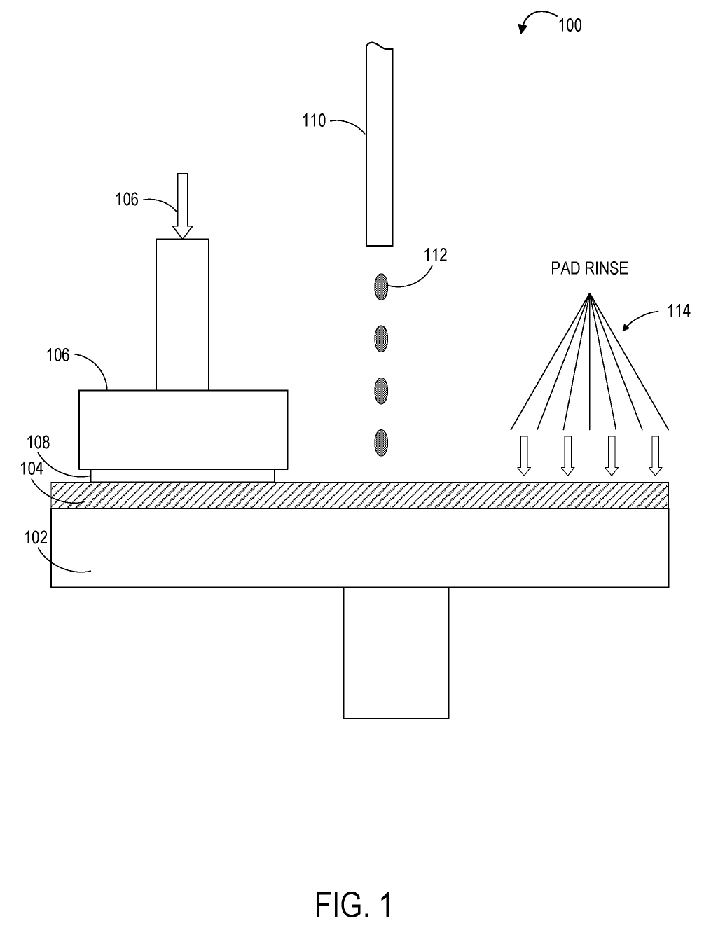

Prior to discussing the disclosed examples of abrasive-free planarization solutions for barrier layer removal, FIG. 1 shows a schematic depiction of an example chemical planarization system 100 according to the present disclosure. System 100 comprises a platen 102 that supports a pad 104. The system 100 further includes a substrate holder 106 configured to hold a substrate 108 against the surface of the pad 104, and a planarization solution introduction system 110 for introducing a planarization solution 112 onto the pad 104. The system 100 further may comprise a pad rinsing system 114 configured to rinse possible contaminant materials from the pad 104, such as complexed materials that have been removed from the surface of the substrate 108. Pad rinsing system 114 also may be used to clean the pad between using different planarization solution chemistries, as described below. Other components (not shown) that optionally may be incorporated into system 100 include, but are not limited to, a spent solution recovery system, a materials recirculation system (e.g. for recirculating the planarization solution in a closed loop process), and a species stripping system.

In conventional CMP processes, the substrate holder pushes the substrate against a polishing pad supported on a platen, and the pad and the substrate are rotated relative to one another in a non-concentric pattern. In such conventional processes, relatively high rates of rotations are used, such as between 40-100 rpm. Further, the substrate is pushed against the pad with a relatively high pressure, such as in a range of 1-4 pounds per square inch. In contrast, a lighter pressure can be used in the disclosed examples, including but not limited to pressures in the range of 0.25 to 0.75 pounds per square inch. The lighter pressure may avoid distortion of the pad shape, and may reduce shear stresses compared to conventional CMP processes. Likewise, a slower rate of rotation may be used in the disclosed examples than with conventional CMP processes, as the rotational motion is not used for abrasion. Instead, rotation of the platen 102 helps to distribute planarization fluid across the pad 104. Any suitable rate of rotation may be used. Examples include rates in a range of 0-60 rpm. More specific examples include rates of 5-30 rpm. As mentioned above, the rate of rotation may be lower than a rate at which a platen rotates in a conventional CMP process, as the rotational motion is not being used in the examples herein to abrade material from a substrate. In other examples, one or more parameters outside of the ranges above can be used where suitable. Further, it will be understood that many different configurations and designs are possible for a variety of platform types (e.g. rotary, linear or belt style, vertically or horizontally oriented rollers, and/or hollow fibers).

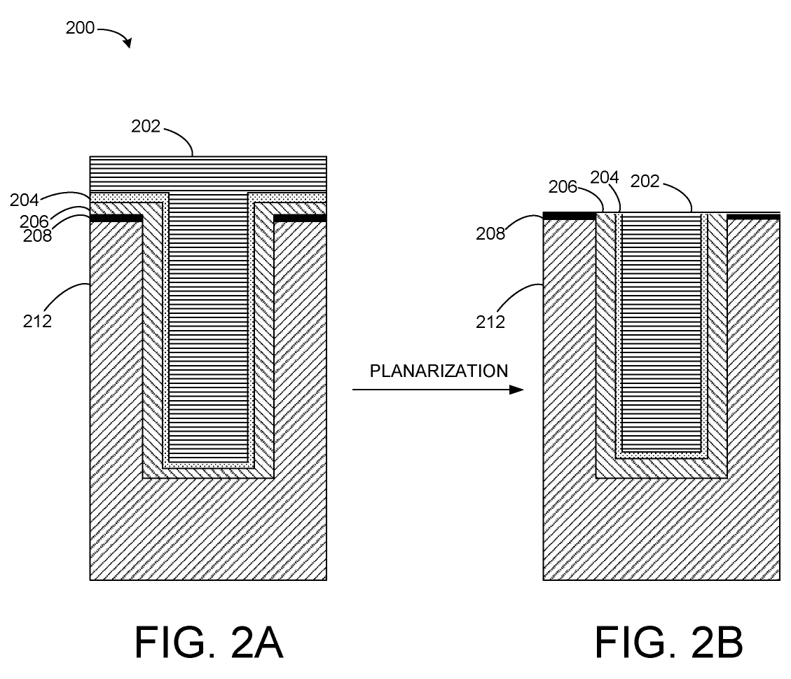

FIGS. 2A-2B schematically illustrate the planarization of a substrate 200 comprising a copper layer 202, and a barrier layer comprising a tantalum layer 204 and a tantalum nitride layer 206 (referred to hereinafter as barrier layer 204/206). Referring to FIG. 2A, in addition to the copper layer 202 and the barrier layer 204/206, the substrate includes a planarization stop layer 208 (e.g. silicon nitride), and a TEOS (tetraethylorthosilicate) or low-k dielectric layer 212.

FIG. 2A shows the substrate 200 before performing CMP to remove overburden of copper layer 202 and portions of barrier layer 204/206. FIG. 2B shows the substrate 200 after performing CMP to remove overburden of copper layer 202 and portions of barrier layer 204/206. The resulting structure is a copper line formed from remaining portions of copper layer 202, which is isolated by isolation layer 206 and barrier layer 204 to prevent copper migration and provide electrical insulation.

As mentioned above, the use of an abrasive slurry to remove portions of a barrier layer by CMP can lead to scratch defects on copper surfaces that are exposed to the CMP slurry. Thus, to avoid the use of an abrasive to remove portions of a barrier layer by CMP, the disclosed examples utilize a barrier layer-activating additive in a barrier layer planarization solution. The barrier layer-activating additive is configured to chemically activate the barrier layer, for example by chemically attacking the barrier layer and/or weaken the chemical bonds of the barrier layer so that the barrier layer can then be removed by chemically functionalized CMP pad. The chemically functionalized pad further can provide additional chelation to chemical components of the barrier layer that are removed from the barrier layer.

For example, where the barrier layer is a tantalum-containing barrier layer, it has been found that guanidine hydrocholoride can effectively increase a rate of tantalum nitride removal compared to a baseline abrasive slurry planarization solution. In an experiment, the following abrasive containing slurry was used as baseline: 0.5% colloidal silica (30 nanometer (nm) size); 0.58% oxalic acid, adjusted to pH 10 with potassium hydroxide (KOH); and 1% of hydrogen peroxide. The TaN blanket removal rate with the control slurry was 149 Angstroms/minute using a chemically functionalized pad, such as the pads disclosed in U.S. Patent Application Publication No. 2024/0391050, titled PADS FOR CHEMICAL PLANARIZATION.

Next, an abrasive-free planarization solution comprising an aqueous solution of 1% by mass guanidine hydrochloride, adjusted to pH 11 using KOH, was tested using the same pad and planarization conditions. The TaN blanket removal rate with this planarization solution was 246 Angstroms/minute. Thus, the guanidine hydrochloride solution outperformed the baseline abrasive slurry solution. In other examples, a concentration of guanidine hydrochloride other than 1% can be used. Examples include concentrations of between 0.1% and 3% by mass guanidine chloride.

In another experiment, a solution of phthalic acid (0.5% by mass in this example), adjusted to pH 11 using KOH, was tested using the same pad and planarization conditions. The TaN blanket removal rate with this planarization solution was greater than 335 Angstroms/minute. Further, a blanket removal rate of tantalum metal (Ta) with this solution was 291 Angstroms/minute. Thus the phthalic acid solution also outperformed the baseline abrasive slurry solution. In other examples, a concentration of phthalic acid other than 0.5% can be used. Examples include concentrations of between 0.1% and 0.56% by mass phthalic acid.

Other examples of materials that may help to activate a tantalum-containing barrier layer include one or more of isophthalic acid, an isophthalic acid substituent, terephthalic acid, a terephthalic acid substituent, potassium carbonate, potassium sulfate, picolinic acid, a picolinic acid substituent, potassium silicate, ethylenediaminetetraacetic acid, an ethylenediaminetetraacetic acid substituent, oxalic acid, an oxalic acid substituent, bis(2-ethylhexyl) phosphate, a bis(2-ethylhexyl) phosphate substituent, potassium perchlorate, benzenesulfonic acid, a benzenesulfonic acid substituent , potassium periodate, phthalic acid, a phthalic acid substituent, salicylic acid, or a salicylic acid substituent. The above-listed substituents are additive molecules that substitute other functional groups for hydrogen atoms in corresponding additive molecules. Suitable substituents include halogen, aryl and alkyl substituents of the above examples.

It is noted that that the planarization solution formulations of the present disclosure perform best in combination with a chemically functionalized pad, such as a polyurethane pad functionalized with carboxylic acid groups bonded to the polyurethane. Examples of these and other functionalized pads that can be suitable for use with a planarization solution as disclosed herein include those disclosed in U.S. patent number 11,545,365, titled CHEMICAL PLANARIZATION, and U.S. Patent Application Publication No. 2024/0391050, titled PADS FOR CHEMICAL PLANARIZATION. The disclosures of each of these applications are hereby incorporated by reference.

It will be understood that the configurations and/or approaches described herein are example in nature, and that these specific embodiments or examples are not to be considered in a limiting sense, because numerous variations are possible. The specific routines or methods described herein can represent one or more of any number of strategies. As such, various acts illustrated and/or described can be performed in the sequence illustrated and/or described, in other sequences, in parallel, or omitted. Likewise, the order of the above-described processes can be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A planarization solution for abrasive-free planarization of a substrate comprising a copper line, a dielectric material, and a barrier layer between the copper line and the dielectric material, the planarization solution comprising a barrier layer-activating additive configured to chemically react with the barrier layer.

2. The planarization solution of claim 1, wherein the barrier layer-activating additive is configured to react with a tantalum-containing barrier layer.

3. The planarization solution of claim 2, wherein the barrier layer-activating additive comprises guanidine or a guanidine substituent.

4. The planarization solution of claim 3, wherein the barrier layer-activating additive comprises one or more of guanidine hydrochloride, a guanidine hydrochloride substituent, guanidine carbonate, or a guanidine carbonate substituent.

5. The planarization solution of claim 2, wherein the barrier layer-activating additive comprises one or more of isophthalic acid, an isophthalic acid substituent, terephthalic acid, a terephthalic acid substituent, potassium carbonate, potassium sulfate, picolinic acid, a picolinic acid substituent, potassium silicate, ethylenediaminetetraacetic acid, an ethylenediaminetetraacetic acid substituent, oxalic acid, an oxalic acid substituent, bis(2-ethylhexyl) phosphate, a bis(2-ethylhexyl) phosphate substituent, potassium perchlorate, benzenesulfonic acid, a benzenesulfonic acid substituent, potassium periodate, phthalic acid, a phthalic acid substituent, salicylic acid, or a salicylic acid substituent.

6. The planarization solution of claim 2, wherein the barrier layer-activating additive comprises one or more of phthalic acid, isophthalic acid, or terephthalic acid.

7. A planarization tool, comprising
a substrate holder;
a pad configured to contact a substate held in the substrate holder; and
a planarization solution introduction system, the planarization solution introduction system comprising a planarization solution containing a barrier layer-activating additive configured to chemically react with the barrier layer.

8. The planarization tool of claim 7, wherein the barrier layer-activating additive is configured to react with a tantalum-containing barrier layer.

9. The planarization tool of claim 8, wherein the barrier layer-activating additive comprises guanidine.

10. The planarization tool of claim 9, wherein the barrier layer-activating additive comprises one or more of guanidine hydrochloride or guanidine carbonate.

11. The planarization tool of claim 8, wherein the barrier layer-activating additive comprises one or more of isophthalic acid, an isophthalic acid substituent, terephthalic acid, a terephthalic acid substituent, potassium carbonate, potassium sulfate, picolinic acid, a picolinic acid substituent, potassium silicate, ethylenediaminetetraacetic acid, an ethylenediaminetetraacetic acid substituent, oxalic acid, an oxalic acid substituent, bis(2-ethylhexyl) phosphate, a bis(2-ethylhexyl) phosphate substituent, potassium perchlorate, benzenesulfonic acid, a benzenesulfonic acid substituent , potassium periodate, phthalic acid, a phthalic acid substituent, salicylic acid, or a salicylic acid substituent.

12. The planarization tool of claim 8, wherein the barrier layer-activating additive comprises one or more of phthalic acid, isophthalic acid, or terephthalic acid.

13. The planarization tool of claim 7, wherein the pad is an abrasive-free pad comprising a chemically-functionalized surface.

14. The planarization tool of claim 13, wherein the pad comprises chelating functional groups to chelate planarized components of the barrier layer.

15. A method of performing abrasive-free planarization of a substrate comprising a copper line, a dielectric material, and a barrier layer between the copper line and the dielectric material, the planarization solution comprising a barrier layer-activating additive configured to chemically react with the barrier layer, the method comprising:
contacting the substrate with an abrasive-free pad comprising a chemically-functionalized surface while exposing the substrate to the planarization solution to thereby planarize at least the barrier layer of the substrate.

16. The method of claim 15, wherein the barrier layer-activating additive is configured to react with a tantalum-containing barrier layer.

17. The method of claim 16, wherein the barrier layer-activating additive comprises guanidine.

18. The method of claim 17, wherein the barrier layer-activating additive comprises one or more of guanidine hydrochloride or guanidine carbonate.

19. The method of claim 16, wherein the barrier layer-activating additive comprises one or more of isophthalic acid, an isophthalic acid substituent, terephthalic acid, a terephthalic acid substituent, potassium carbonate, potassium sulfate, picolinic acid, a picolinic acid substituent, potassium silicate, ethylenediaminetetraacetic acid, an ethylenediaminetetraacetic acid substituent, oxalic acid, an oxalic acid substituent, bis(2-ethylhexyl) phosphate, a bis(2-ethylhexyl) phosphate substituent, potassium perchlorate, benzenesulfonic acid, a benzenesulfonic acid substituent , potassium periodate, phthalic acid, a phthalic acid substituent, salicylic acid, or a salicylic acid substituent.

20. The method of claim 16, wherein the barrier layer-activating additive comprises one or more of phthalic acid, isophthalic acid, or terephthalic acid.
